(19) United States
(12) Patent Application Publication
(10) Pub. No.: US 2008/0211556 A1
(43) Pub. Date: Sep. 4, 2008

(54) SEMICONDUCTOR INTEGRATED CIRCUIT

(76) Inventor: Akira MASUO, Osaka (JP)

Correspondence Address: MCDERMOTT WILL & EMERY LLP, 600 13TH STREET, NW, WASHINGTON, DC, 20005-3096, US

(21) Appl. No.: 12/027,411

(22) Filed: Feb. 7, 2008

(30) Foreign Application Priority Data
Mar. 1, 2007 (JP) 2007-051170

(51) Int. Cl. H03L 7/00

(52) U.S. Cl. 327/161

(57) ABSTRACT

A delay clock circuit for delaying an input clock signal includes cascade connection of components each comprising first and second inverters. A delay clock control circuit is operated so that a through current can pass through a connection node between the first and second inverters for causing charge competition for a given period of time in transition of the input to the component. The delay clock control circuit includes a P-type transistor disposed, for example, between a power line and the connection node for receiving the output of the second inverter at the gate thereof.

### CROSS-REFERENCE TO RELATED APPLICATIONS

This application claims priority under 35 U.S.C. §119 on Patent Application No. 2007-051170 filed in Japan on Mar. 1, 2007, the entire contents of which are hereby incorporated by reference.

### BACKGROUND OF THE INVENTION

The present invention relates to a semiconductor integrated circuit including a delay clock circuit for delaying an input clock signal so as to use a resultant delay clock signal as, for example, an enable signal for a sense amplifier or the like.

A latch type sense amplifier used in a semiconductor memory or the like needs a timing generator circuit for generating an enable signal for itself. The timing generator circuit includes, as the simplest configuration, a plurality of cascade connected inverters. An enable signal for a sense amplifier can be operated at optimum timing by adjusting the number of gate stages of the inverters.

In a conventional technique, the delay time of a delay clock signal is controlled in accordance with the frequency change of an input clock signal. Specifically, a pulse signal based on a fall edge of the input clock signal is generated through a combination of an inverter, a NAND circuit and a NOR circuit, so that the driving performance of each inverter included in an inverter chain used for generating the delay clock signal can be changed in accordance with the thus generated pulse signal (see Japanese Laid-Open Patent Publication No. 2001-344972).

In the above-described conventional technique, optimum timing can be generated in accordance with the frequency change of the input clock signal. However, it needs a large scale circuit for generating the pulse signal used for changing the driving performance of the inverter Also, the circuit used for generating the pulse signal and the inverter included in the inverter chain are not provided with any means for adjusting the delay time in accordance with transistor variation.

### SUMMARY OF THE INVENTION

An object of the invention is providing a delay clock circuit having transistor variation tolerance without increasing the circuit area.

The semiconductor integrated circuit of this invention includes a delay clock circuit for delaying an input clock signal, and the delay clock circuit includes cascade connection of components each comprising first and second inverters, and each of the components includes a delay clock control circuit operated in such a manner that a through current passes through a connection node between the first and second inverters for causing charge competition for a given period of time in transition of an input to the component.

According to the present invention, in each component of the delay clock circuit, the charge competition derived from a through current can be caused on the connection node between the first and second inverters for a given period of time in transition of the input to the component. Therefore, a delay clock signal can be further delayed. Accordingly, activation of, for example, a sense amp. enable signal can be further delayed. As a result, a micro potential difference between a pair of bit lines can be increased, so as to suppress the probability of malfunction and to improve the yield of the semiconductor integrated circuit.

### BRIEF DESCRIPTION OF THE DRAWINGS

FIG. 1 is a block diagram for showing an exemplified architecture of an SRAM described as an example of a semiconductor integrated circuit of this invention.

FIG. 2 is a circuit diagram for schematically showing an exemplified configuration of a conventional delay clock signal usable in the SRAM of FIG. 1.

FIG. 3 is a circuit diagram for schematically showing an exemplified configuration of a delay clock circuit according to an embodiment of the invention usable in the SRAM of FIG. 1.

FIG. 4 is a timing chart for explaining the operations performed in the SRAM of FIG. 1 in employing the delay clock circuits of FIGS. 2 and 3.

FIG. 5 is a circuit diagram for schematically showing another exemplified configuration of the delay clock circuit according to the embodiment of the invention usable in the SRAM of FIG. 1.

FIG. 6 is a timing chart for explaining the operation performed in the SRAM of FIG. 1 in employing the delay clock circuit of FIG. 5.

FIG. 7 is a circuit diagram for schematically showing another exemplified configuration of the delay clock circuit according to the embodiment of the invention usable in the SRAM of FIG. 1.

FIG. 8 is a timing chart for explaining the operation performed in the SRAM of FIG. 1 in employing the delay clock circuit of FIG. 7.

FIG. 9 is a circuit diagram for schematically showing an exemplified configuration of a row decoder used in the SRAM of FIG. 1.

FIG. 10 is a timing chart for explaining the operation of the SRAM of FIG. 1 including the row decoder of FIG. 9.

FIG. 11 is a circuit diagram for schematically showing an exemplified configuration of a row decoder replica used in the SRAM of FIG. 1.

FIG. 12 is a timing chart for explaining the operation of the SRAM of FIG. 1 performed in employing a memory cell replica.

FIG. 13 is a circuit diagram for schematically showing an exemplified configuration of a write auxiliary circuit used in the SRAM of FIG. 1.

FIG. 14 is a timing chart for explaining the operation of the SRAM of FIG. 1 performed in employing the write auxiliary circuit.

FIG. 15 is a diagram for schematically showing an exemplified layout of the SRAM of FIG. 1.

FIG. 16 is a diagram for schematically showing an exemplified layout of the delay clock circuit according to the embodiment of the invention.

FIG. 17 is a diagram for schematically showing another exemplified layout of the delay clock circuit according to the embodiment of the invention.

FIG. 18 is a diagram for schematically showing another exemplified layout of the delay clock circuit according to the embodiment of the invention.

### DETAILED DESCRIPTION OF THE INVENTION

A preferred embodiment of the invention will now be described with reference to the accompanying drawings.

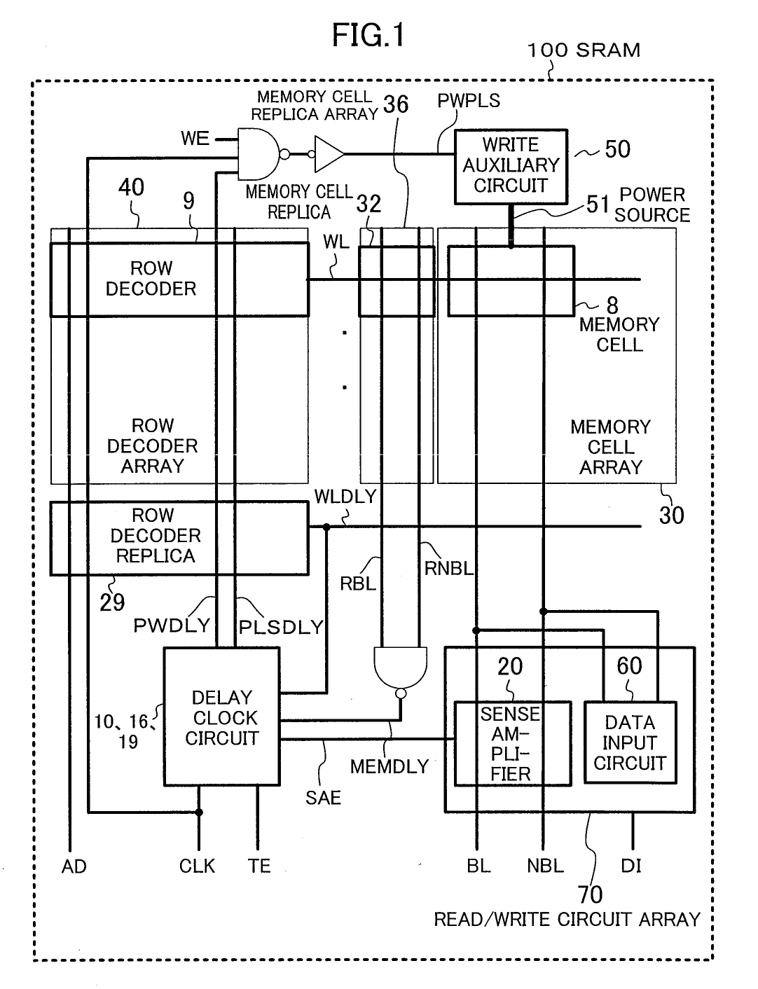

FIG. 1 shows an exemplified architecture of an SRAM (static random access memory) 100 described as an example of a semiconductor integrated circuit of this invention. The SRAM 100 of FIG. 1 includes a delay clock circuit 10, 16 or 19, a memory cell array 30, a row decoder 40, a write auxiliary circuit 50 and a read/write circuit array 70. The read/write circuit array 70 has a structure in the form of an array including a sense amplifier 20 and a data input circuit 60.

More specifically, the delay clock circuit 10, 16 or 19 outputs, in accordance with an input clock signal CLK, a sense amp. enable signal SAE, a word line pulse forming signal PLSDLY used for pulse controlling a word line WL and a write pulse forming signal PWDLY used for pulse controlling the write auxiliary circuit 50. These signals SAE, PLSDLY and PWDLY correspond to delay clock signals. The sense amplifier 20 is operated in accordance with the sense amp. enable signal SAE for detecting and outputting a micro potential difference between a pair of bit lines BL and NBL. The memory cell array 30 includes a plurality of memory cells 8 arranged in the form of a matrix. A plurality of word lines WL are provided respectively correspondingly to rows of the memory cell array 30, and a plurality of bit line pairs BL and NBL are provided respectively correspondingly to columns of the memory cell array 30.

The row decoder array 40 includes a plurality of row decoders 9 provided respectively correspondingly to the rows of the memory cell array 30. Each row decoder 9 outputs a pulse signal to the corresponding word line WL in accordance with the input clock signal CLK and the word line pulse forming signal PLSDLY. The write auxiliary circuit 50 is provided correspondingly to each column of the memory cell array 30 and is connected to a power source 51 of the corresponding memory cells 8, and outputs a pulse signal to the power source 51 in accordance with the write pulse forming signal PWDLY. The data input circuit 60 outputs a potential difference to the bit line pair BL and NBL in accordance with an input data signal DI.

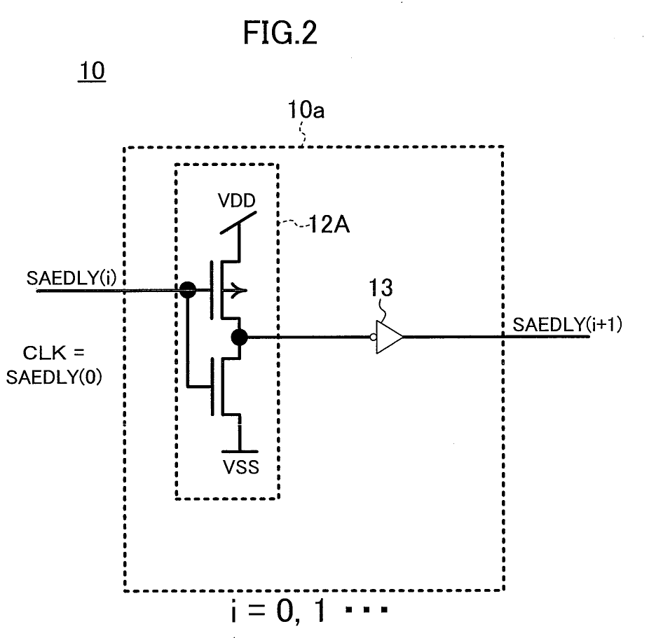

FIG. 2 is a diagram for schematically showing an exemplified configuration of the delay clock circuit 10 according to a conventional technique usable in the SRAM 100 of FIG. 1. In FIG. 2, a reference numeral 12A denotes a first inverter and a reference numeral 13 denotes a second inverter, and the output of the first inverter 12A is connected to the input of the second inverter 13. As shown in FIG. 2, the delay clock circuit 10 has an array structure including the first inverter 12A and the second inverter 13 as one component. In other words, the delay clock circuit 10 includes cascade connection of components 10a each composed of the serially connected first and second inverters 12A and 13.

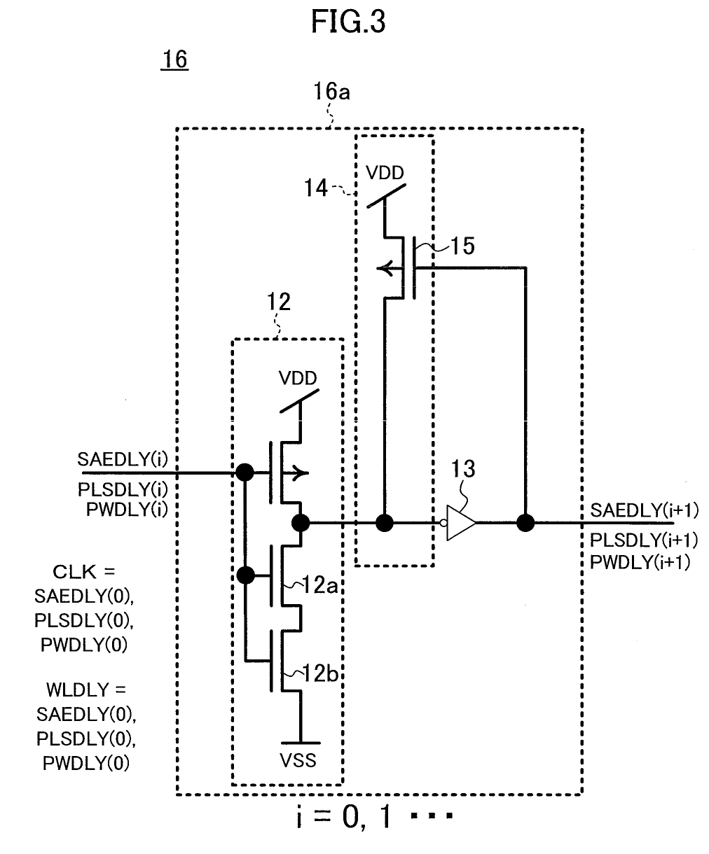

FIG. 3 is a diagram for showing an exemplified configuration of the delay clock circuit 16 according to the embodiment of the invention usable in the SRAM 100 of FIG. 1. In the configuration of FIG. 3, a delay clock control circuit 14 is used in addition to the conventional configuration of FIG. 2. Specifically, the delay clock circuit 16 includes cascade connection of components 16a each composed of serially connected first and second inverters 12 and 13 and the delay clock control circuit 14. The delay clock control circuit 14 is connected to a connection node between the first and second inverters 12 and 13 and to an output node of the second inverter 13. This delay clock control circuit 14 is operated in such a manner that a through current passes through the connection node between the first and second inverters 12 and 13 so as to cause charge competition for a given period of time in transition of the input to the component 16a.

In the configuration of FIG. 3, the delay clock control circuit 14 includes a first P-type transistor 15 that is connected between a power line VDD and the connection node between the first and second inverters 12 and 13 and receives the output of the second inverter 13 at its gate. It is noted that the first P-type transistor 15 may be replaced with a plurality of P-type transistors serially connected to one another in plural stages. Alternatively, the first P-type transistor 15 may be replaced with an inverter.

Moreover, in the configuration of FIG. 3, the first inverter 12 includes a plurality of N-type transistors 12a and 12b that are connected between a ground line VSS and the connection node between the first and second inverters 12 and 13 and are serially connected to one another in plural stages (two stages in the drawing). It is noted that the number of P-type or N-type transistors used in the first or second inverter 12 or 13 may be one or plural serially connected in plural stages.

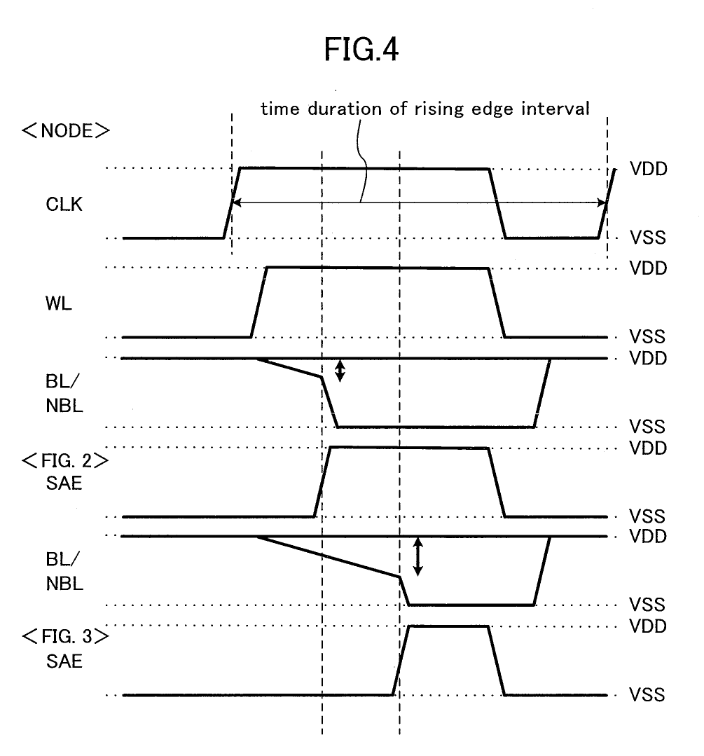

FIG. 4 is a timing chart for explaining the operations performed in the SRAM of FIG. 1 in employing the delay clock circuit 10 of FIG. 2 and the delay clock circuit 16 of FIG. 3. In this case, a read operation is described and the operations are compared between the conventional configuration shown in FIG. 2 and the configuration of this embodiment shown in FIG. 3.

The input clock signal CLK is input to the row decoder 9, so as to activate the output of the row decoder 9, namely, the corresponding word line WL. As a result of the activation of the word line WL, each of the corresponding memory cells 8 causes a micro potential difference between the bit line pair BL and NBL. On the other hand, the input clock signal CLK is input to the delay clock circuit 10 or 16.

In the conventional configuration shown in FIG. 2, when the input clock signal CLK undergoes a high transition (is changed to H level), the P-type transistor is turned off and the N-type transistor is turned on in the first inverter 12A, and hence, a low signal (a signal at L level) is output. Therefore, the signal at L level is supplied to the input of the second inverter 13 disposed at the next stage. Accordingly, the P-type transistor is turned on and the N-type transistor is turned off in the second inverter 13, and hence, a signal at H level is output. The timing for activating the sense amp. enable signal SAE can be controlled by changing the number of gate stages. When the sense amp. enable signal SAE is activated, the sense amplifier 20 detects and outputs the micro potential difference between the bit line pair BL and NBL.

On the other hand, in the configuration of this embodiment shown in FIG. 3, when the input clock signal CLK is at L level, the P-type transistor is turned on and the N-type transistors are turned off in the first inverter 12, and hence, a signal at H level is output. Therefore, the signal at H level is supplied to the input of the second inverter 13 provided at the next stage. Accordingly, the P-type transistor is turned off and the N-type transistor is turned on in the second inverter 13, and hence, a signal at L level is output. The signal at L level output from the second inverter 13 is input to the gate of the first P-type transistor 15 of the delay clock control circuit 14. As a result, the first P-type transistor 15 is turned on.

When the input clock signal CLK undergoes a H transition, the P-type transistor is turned off and the N-type transistors are turned on in the first inverter 12, and hence, a signal at L level is output. At this point, the first P-type transistor 15 of the delay clock control circuit 14 is in an on state, and as a result, charge competition derived from a through current between charge discharged by the N-type transistors of the first inverter 12 and charge charged by the first P-type transistor 15 is caused for a given period of time. Thereafter, the signal at L level is supplied to the input of the second inverter 13 provided at the next stage. Therefore, the P-type transistor is turned on and the N-type transistor is turned off in the second inverter 13, and hence, a signal at H level is output. Thus, the charge competition derived from a through current can be caused for a given period of time not only by changing the number of gate stages but also by additionally providing the first P-type transistor 15 of the delay clock control circuit 14, and in this manner, the timing for activating the sense amp. enable signal SAE can be controlled. When the sense amp. enable signal SAE is activated, the sense amplifier 20 detects and outputs the micro potential difference between the bit line pair BL and NBL.

In this manner, when the delay clock circuit 16 of this embodiment shown in FIG. 3 is employed, the charge competition derived from a through current can be caused for a given period of time by the first P-type transistor 15 of the delay clock control circuit 14 and the N-type transistors of the first inverter 12. Therefore, the activation of the sense amp. enable signal SAE can be further delayed than in the conventional configuration. In other words, in the case where transistor variation is large, and more particularly, in the case where the driving performance of a P-type transistor is high and the driving performance of an N-type transistor is low in the SRAM 100, the activation of the sense amp. enable signal SAE can be further delayed than in the conventional configuration merely by providing one additional transistor device without largely increasing the circuit area. Accordingly, the micro potential difference between the bit line pair BL and NBL is increased, so as to suppress the probability of malfunction and to improve the yield of the SRAM and a semiconductor integrated circuit including the SRAM.

The given period of time when the charge competition derived from a through current is caused is preferably shorter than a rising edge interval of the input clock signal CLK.

Furthermore, in the delay clock circuit 16 of FIG. 3, the sum of gate widths of the plural N-type transistors serially connected to one another in plural stages and included in the first inverter 12 is preferably not less than twice and not more than 40 times as large as the gate width of the first P-type transistor 15 of the delay clock control circuit 14. In the case where the proportion of the total gate width is smaller than twice, the driving performance for discharging the charge of the N-type transistors of the first inverter 12 is lower than the dividing performance for charging the charge of the first P-type transistor 15 of the delay clock control circuit 14, and hence, the malfunction of the delay clock circuit 16 is caused. On the other hand, when the proportion of the total gate width exceeds 40 times, the effect to increase the delay time by causing the charge competition derived from a through current is minimally attained. Accordingly, when the circuit is designed to have the total gate width in the above-described range, the timing for activating the sense amp. enable signal SAE can be optimized.

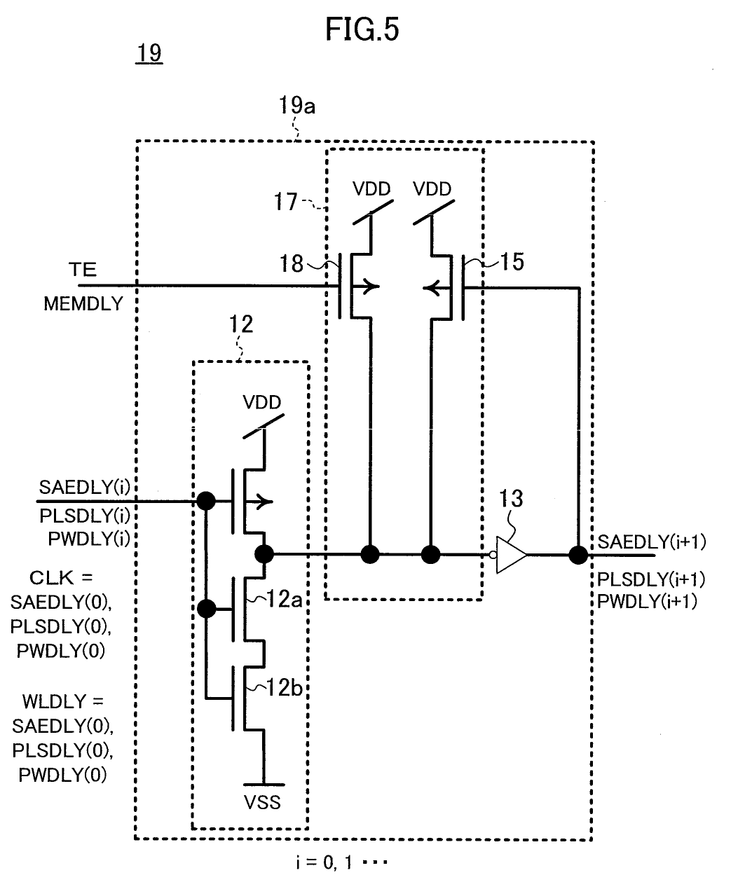

FIG. 5 is a diagram for schematically showing an exemplified configuration of the delay clock circuit 19 according to the embodiment of the invention usable in the SRAM 100 of FIG. 1. In the configuration of FIG. 5, a delay clock control circuit 17 is provided in addition to the conventional configuration of FIG. 2. Specifically, the delay clock control circuit 19 includes cascade connection of components 19a each composed of the serially connected first and second inverters 12 and 13 and the delay clock control circuit 17. The delay clock control circuit 17 is connected to the connection node between the first and second inverters 12 and 13 and the output node of the second inverter 13. Also, the delay clock control circuit 17 includes, as compared with the delay clock control circuit 14 of FIG. 3, a second P-type transistor 18 in addition to the first P-type transistor 15. The second P-type transistor 18 is provided in parallel to the first P-type transistor 15 between the power line VDD and the connection node between the first and second inverters 12 and 13, and receives a first external signal TE at its gate. In other words, the second P-type transistor 18 is controlled to be turned on/off in accordance with the first external signal TE.

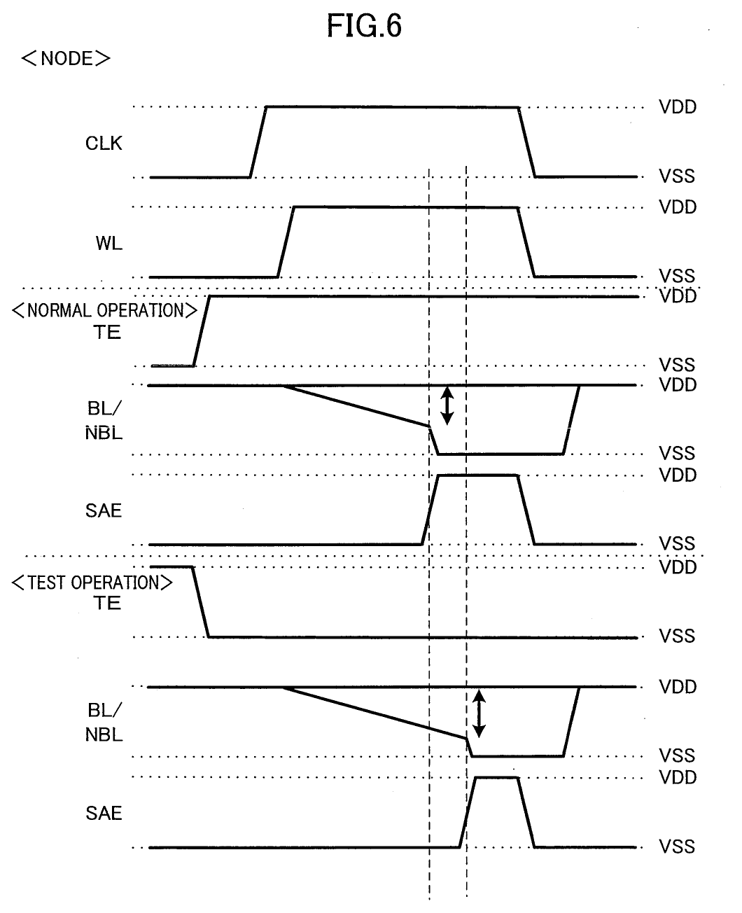

FIG. 6 is a timing chart for explaining the operation performed in the SRAM of FIG. 1 in employing the delay clock circuit 19 of FIG. 5. Herein, a read operation is described. Also, the description is given on the assumption that the first external signal TE is a signal for switching between a normal operation and a test operation. Furthermore, the basic operation of the SRAM 100 is the same as that shown in FIG. 4 and hence the description is omitted.

In the normal operation, the first external signal TE undergoes a H transition for turning off the second P-type transistor 18. At this point, a transistor used for further delaying a delay clock signal in the delay clock control circuit 17 is the first P-type transistor 15 alone, and thus, the same effect as that attained by the configuration of FIG. 3 can be attained.

In the test operation, the first external signal TE undergoes a L transition for turning on the second P-type transistor 18. At this point, not only the first P-type transistor 15 but also the second P-type transistor 18 works as transistors used for further delaying a delay clock signal in the delay clock control circuit 17. Thus, the delay time is further increased than in the configuration of FIG. 3.

In this manner, in the case where the delay clock circuit 19 of this embodiment shown in FIG. 5 is employed, the charge competition derived from a through current can be caused for a given period of time in the test operation by the first and second P-type transistors 15 and 18 of the delay clock control circuit 17 and the N-type transistors of the first inverter 12. Therefore, the activation of the sense amp. enable signal SAE can be further delayed. In other words, the activation of the sense amp. enable signal SAE can be further delayed in the test operation merely by providing a further additional transistor device without largely increasing the circuit area. Accordingly, the micro potential difference between the bit line pair BL and NBL is increased, so as to suppress the probability of malfunction, to accelerate improvement in specification of a fault detection portion and in fault coverage in the SRAM and a semiconductor integrated circuit including the SRAM, and to improve the yield.

It is noted that the first external signal TE is not limited to the signal for switching between the normal operation and the test operation. For example, when the first external signal TE is steadily kept at L level, the activation of the sense amp. enable signal SAE can be further delayed. Accordingly, the micro potential difference between the bit line pair BL and NBL can be further increased so as to suppress the probability of malfunction.

Moreover, the first P-type transistor 15 may be omitted in the configuration of FIG. 5.

Furthermore, in the delay clock circuit 19 of FIG. 5, the sum of gate widths of the plural N-type transistors serially connected to one another in plural stages and included in the first inverter 12 is preferably not less than twice and not more than 40 times as large as the sum of gate widths of the first and second P-type transistors 15 and 18 of the delay clock control circuit 17. In the case where the proportion of the total gate width is smaller than twice, the driving performance for discharging the charge of the N-type transistors of the first inverter 12 is lower than the dividing performance for charging the charge of the first and second P-type transistors 15 and 18 of the delay clock control circuit 17, and hence, the malfunction of the delay clock circuit 19 is caused. On the other hand, when the proportion of the total gate width exceeds 40 times, the effect to increase the delay time by causing the charge competition derived from a through current is minimally attained. Accordingly, when the circuit is designed to have the total gate width in the above-described range, the timing for activating the sense amp. enable signal SAE can be optimized.

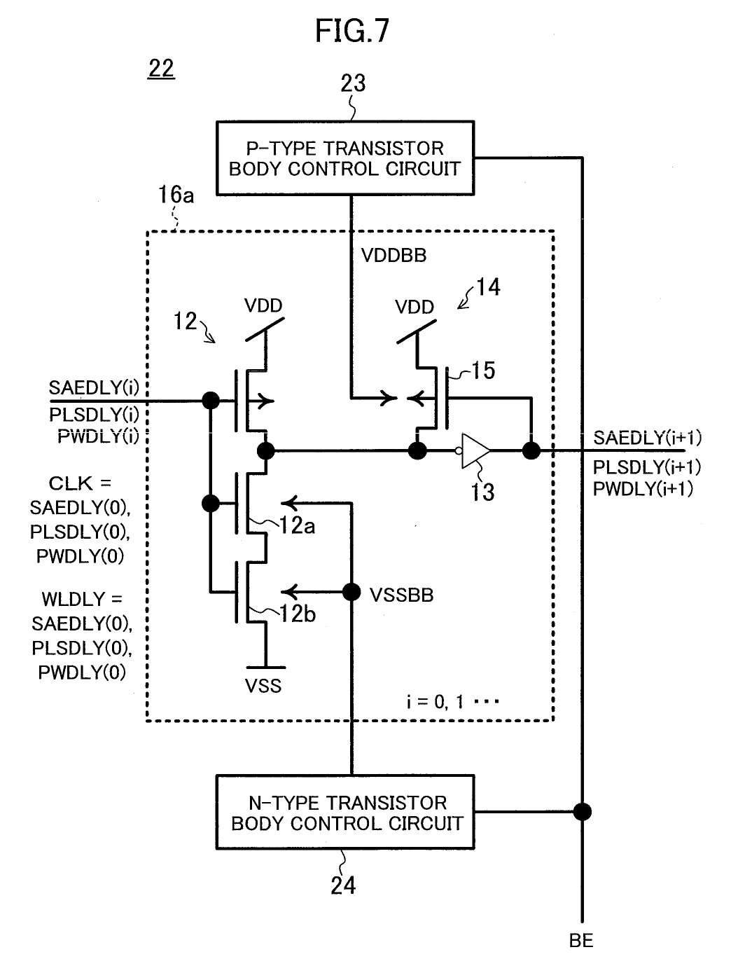

FIG. 7 is a diagram for schematically showing an exemplified configuration of the delay clock circuit 22 according to the embodiment of the invention usable in the SRAM 100 of FIG. 1. In the configuration of FIG. 7, a P-type transistor body control circuit 23 and an N-type transistor body control circuit 24 are additionally provided in the delay clock circuit 16 of FIG. 3. The P-type transistor body control circuit 23 controls, by using a signal VDDBB, the body potential of the first P-type transistor 15 included in the delay clock control circuit 14 in accordance with a second external signal BE. The N-type transistor body control circuit 24 controls, by using a signal VSSBB, the body potential of the plural N-type transistors 12a and 12b included in the first inverter 12 also in accordance with the second external signal BE.

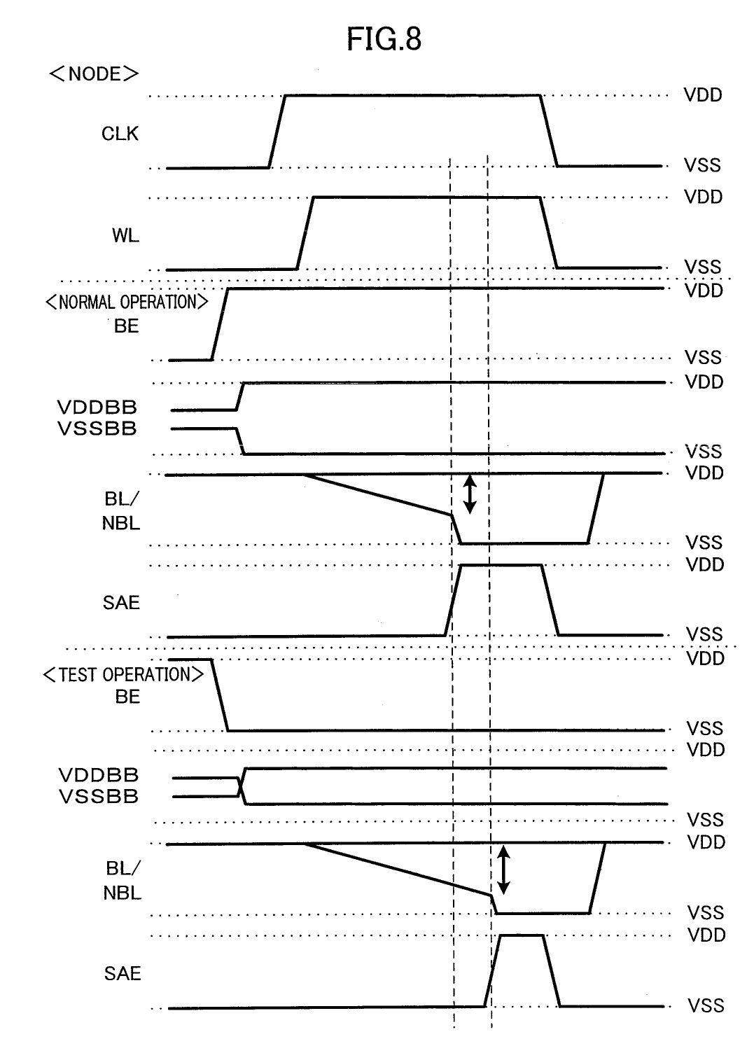

FIG. 8 is a timing chart for explaining the operation performed in the SRAM of FIG. 1 in employing the delay clock circuit 22 of FIG. 7. Herein, a read operation is described. Also, the description is given on the assumption that the second external signal BE is a signal for switching between a normal operation and a test operation. Furthermore, the basic operation of the SRAM 100 is the same as that shown in FIG. 4 and hence the description is omitted.

In the normal operation, in accordance with the second external signal BE, the P-type transistor body control circuit 23 does not apply a bias to the body of the first P-type transistor 15 by the output signal VDDBB and the N-type transistor body control circuit 24 does not apply a bias to the body of the N-type transistors of the first inverter 12 by the output signal VSSBB. Therefore, the threshold voltages of the first P-type transistor 15 and the N-type transistors 12a and 12b of the first inverter 12 are not changed, and hence, the same effect as that attained by the configuration of FIG. 3 can be attained.

In the test operation, in accordance with a second external signal BE, the P-type transistor body control circuit 23 applies a forward bias to the body of the first P-type transistor 15 by the output signal VDDBB and the N-type transistor body control circuit 24 applies a reverse bias to the body of the N-type transistors 12a and 12b of the first inverter 12 by the output signal VSSBB. Therefore, the current driving performance of the first P-type transistor 15 is increased because the absolute value of its threshold voltage is reduced, and the current driving performance of the N-type transistors 12a and 12b of the first inverter 12 is reduced because the absolute value of their threshold voltage is increased. As a result, the charge competition is caused on the connection node, so as to further increase the delay time than in the configuration of FIG. 3.

In this manner, in the case where the delay clock circuit 22 of FIG. 7 according to the embodiment is employed, the absolute value of the threshold voltage of the first P-type transistor 15 included in the delay clock control circuit 14 can be reduced and the absolute value of the threshold voltage of the N-type transistors 12a and 12b included in the first inverter 12 can be increased in the test operation. Therefore, the driving performance of the first P-type transistor 15 is increased and the driving performance of the N-type transistors 12a and 12b of the first inverter 12 is reduced, and hence, the charge competition derived from a through current can be caused for a given period of time. Thus, the activation of the sense amp. enable signal SAE can be further delayed in the test operation. Accordingly, the micro potential difference between the bit line pair BL and NBL can be increased, so as to suppress the probability of malfunction, to accelerate improvement in specification of a fault detection portion and in fault coverage in the SRAM and a semiconductor integrated circuit including the SRAM, and to improve the yield.

It is noted that the second external signal BE is not limited to the signal for switching between the normal operation and the test operation. For example, the forward bias and the reverse bias may be steadily applied respectively to the body of the first P-type transistor 15 and the body of the N-type transistors 12a and 12b of the first inverter 12 in accordance with the second external signal BE. Thus, the activation of the sense amp. enable signal SAE can be further delayed, so as to further increase the micro potential difference between the bit line pair BL and NBL and to suppress the probability of malfunction. Also, in the configuration of FIG. 7, merely one of the P-type transistor body control circuit 23 and the N-type transistor body control circuit 24 may be provided.

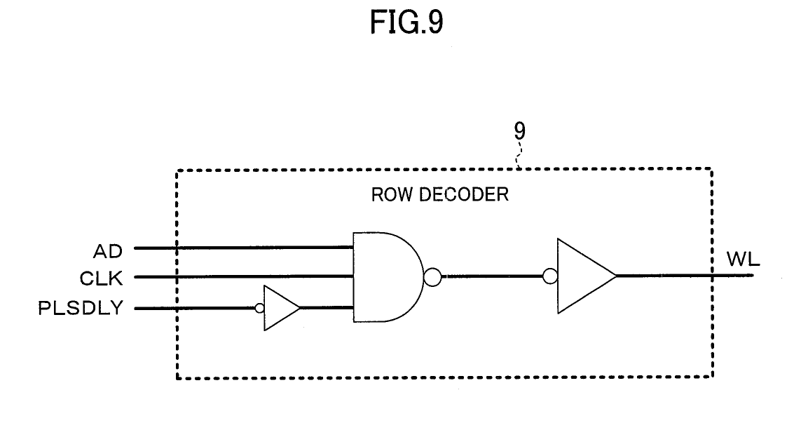

FIG. 9 is a diagram for schematically showing an exemplified configuration of the row decoder 9 used in the SRAM 100 of FIG. 1. In the configuration of FIG. 9, the row decoder 9 outputs a pulse signal to the word line WL when it is selected in accordance with an address signal AD. The input clock signal CLK is used for forming a pulse edge on a rising side of the pulse signal output to the word line WL. The word line pulse forming signal PLSDLY is used for forming a pulse edge on a falling side of the pulse signal output to the word line WL. The row decoder 9 receives a delay clock signal output from the delay clock circuit 16, 19 or 22 as the word line pulse forming signal PLSDLY.

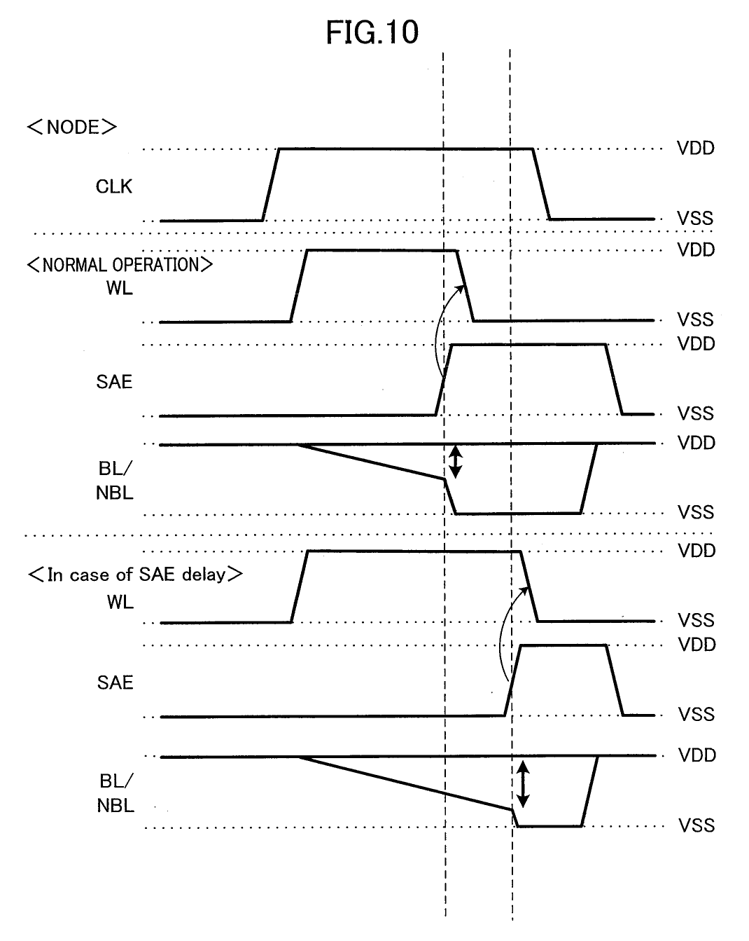

FIG. 10 is a timing chart for explaining the operation of the SRAM 100 of FIG. 1 including the row decoder 9 of FIG. 9. Herein, a read operation is described. Also, FIG. 10 shows a normal operation and an operation performed when the sense amp. enable signal SAE is delayed. At this point, the normal operation employs operation timing set at the stage of design, and when any of various conditions such as process, a voltage, a temperature and a frequency is varied from the designed condition, the sense amp. enable signal SAE is delayed.

In FIG. 10, the input clock signal CLK is input to the row decoder 9, so as to activate the output of the row decoder 9, namely, the word line WL. Each of the corresponding memory cells 8 causes a micro potential difference between the corresponding bit line pair BL and NBL when the word line WL is activated. On the other hand, the input clock signal CLK is input to the delay clock circuit 16, 19 or 22. The sense amplifier 20 detects and outputs the micro potential difference between the bit line pair BL and NBL in response to the activation of the sense amp. enable signal SAE corresponding to the output of the delay clock circuit 16, 19 or 22.

The output of the row decoder 9, namely, the word line WL, is deactivated in accordance with the word line pulse forming signal PLSDLY corresponding to the output of the delay clock circuit 16, 19 or 22. Even when the various conditions are varied, since the sense amp. enable signal SAE and the word line pulse forming signal PLSDLY are output from the same delay clock circuit 16, 19 or 22, the timing of these signals show the same tendency against the variation of the conditions. Accordingly, in the case where the sense amp. enable signal SAE is delayed, the word line pulse forming signal PLSDLY is similarly delayed. Therefore, the pulse width of the word line WL is increased.

In this manner, in the configurations of FIGS. 1 and 9, the timings of the word line pulse forming signal PLSDLY and the sense amp. enable signal SAE show the same tendency against the variation of the conditions. Therefore, in the case where the sense amp. enable signal SAE is delayed, the word line pulse forming signal PLSDLY is also similarly delayed, and hence, the pulse width of the word line WL is increased. Accordingly, the micro potential difference between the bit line pair BL and NBL is increased, so as to suppress the probability of malfunction and to improve the yield of the SRAM and a semiconductor integrated circuit including the SRAM.

Although the sense amp. enable signal SAE and the word line pulse forming signal PLSDLY are output from the same delay clock circuit 16, 19 or 22, these signals may not be output through the same number of gate stages.

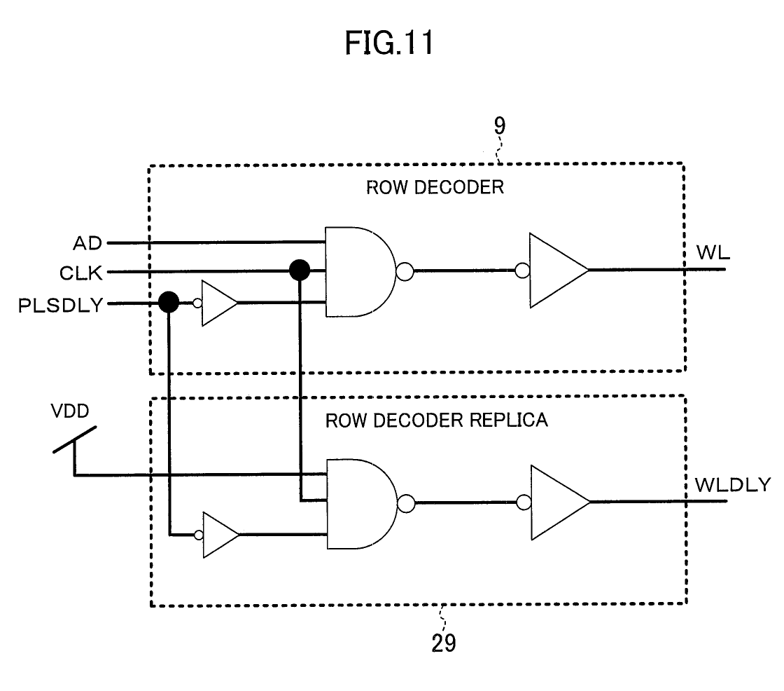

FIG. 11 is a diagram for schematically showing an exemplified configuration of a row decoder replica (RDR) 29 included in the SRAM 100 of FIG. 1. In the configuration of FIG. 11, the row decoder replica 29 has the same configuration as the row decoder 9 but receives, instead of the address signal AD, a power voltage VDD or a signal according to the power voltage VDD so as to be always selected. In other words, the row decoder replica 29 outputs a pulse signal as a word line delay signal WLDLY at the same timing as the row decoder 9 selected in accordance with the address signal AD. The word line delay signal WLDLY output from the row decoder replica 29 is input to the delay clock circuit 16, 19 or 22 as the input clock signal.

In this manner, in the configuration of FIG. 11, the word line delay signal WLDLY sent from the row decoder replica 29 having the same configuration as the row decoder 9 is activated at substantially the same timing as the word line WL. Therefore, variation in the input timing to the delay clock circuit 16, 19 or 22 can be suppressed. It is noted that the word line pulse forming signal PLSDLY may be omitted in this case.

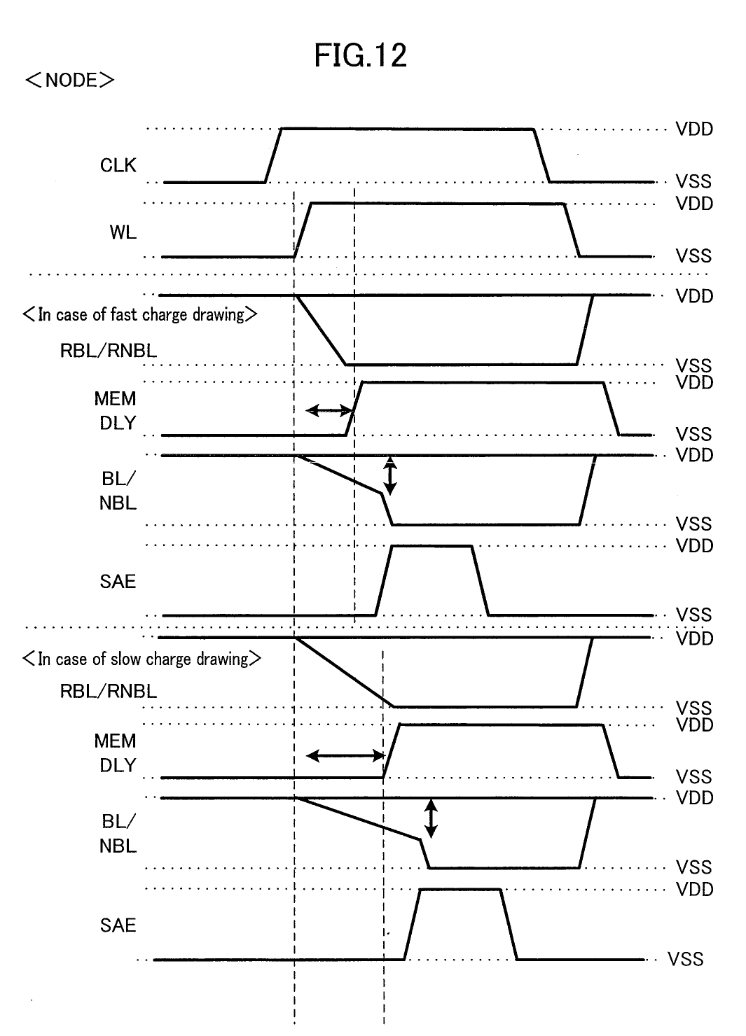

FIG. 12 is a timing chart for showing an operation performed in the SRAM 100 of FIG. 1 in employing a memory cell replica 32. In the architecture of FIG. 1, a memory cell replica array 36 includes a plurality of memory cell replicas 32 having the same configuration as the memory cell 8 and arranged in the form of a column. A pair of replica bit lines RBL and RNBL are provided correspondingly to the column of the memory cell replicas 32. Also, a memory cell replica delay signal MEMDLY is a signal for indicating whether or not there is a given potential difference between the replica bit line pair RBL and RNBL, and is herein assumed to become H level when the given potential difference is caused between the replica bit line pair RBL and RNBL. The delay clock circuit 19 receives, instead of the second external signal TE, a memory cell replica delay signal MEMDLY at the gate of the second P-type transistor 18 included in the delay clock control circuit 17.

In the architecture of FIG. 1, the variation of the memory cells 8 affects the memory cell replicas 32. Therefore, as shown in FIG. 12, in the case where charge is drawn quickly in the memory cells 8 and the memory cell replica 32, the timing for turning off the second P-type transistor 18 included in the delay clock circuit 19 is early, and hence, the timing for activating the sense amplifier 20 by the sense amp. enable signal SAE is also early. On the other hand, in the case where charge is drawn slowly in the memory cells 8 and the memory cell replica 32, the period when the second P-type transistor 18 included in the delay clock circuit 19 is in an on state is elongated and the timing for turning it off is delayed, and hence, the timing for activating the sense amplifier 20 by the sense amp. enable signal SAE is also delayed.

In this manner, the sense amplifier 20 is activated with the micro potential difference between the bit line pair BL and NBL sufficiently secured regardless of the variation in the memory cells 8, and therefore, the yield can be improved.

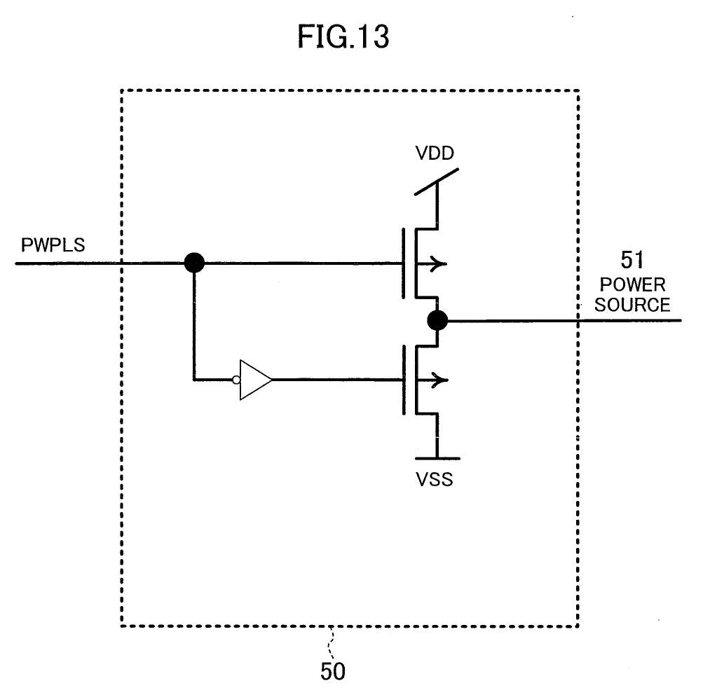

FIG. 13 is a diagram for showing an exemplified configuration of the write auxiliary circuit 50 included in the SRAM 100 of FIG. 1. In the configuration of FIG. 13, a P-type transistor is used for drawing charge so as to avoid excessive voltage drop of the power source 51. In the architecture of FIG. 1, the write auxiliary circuit 50 is provided correspondingly to each column of the memory cells 8 for lowering the potential of the power source 51 of the corresponding memory cells during a period when a write auxiliary pulse signal PWPLS is output. The write auxiliary pulse signal PWPLS is generated based on a write enable signal WE and the write pulse forming signal PWDLY output as the delay clock signal from the delay clock circuit 16, 19 or 22. The write pulse forming signal PWDLY is used for forming a pulse edge of the write auxiliary pulse signal PWPLS.

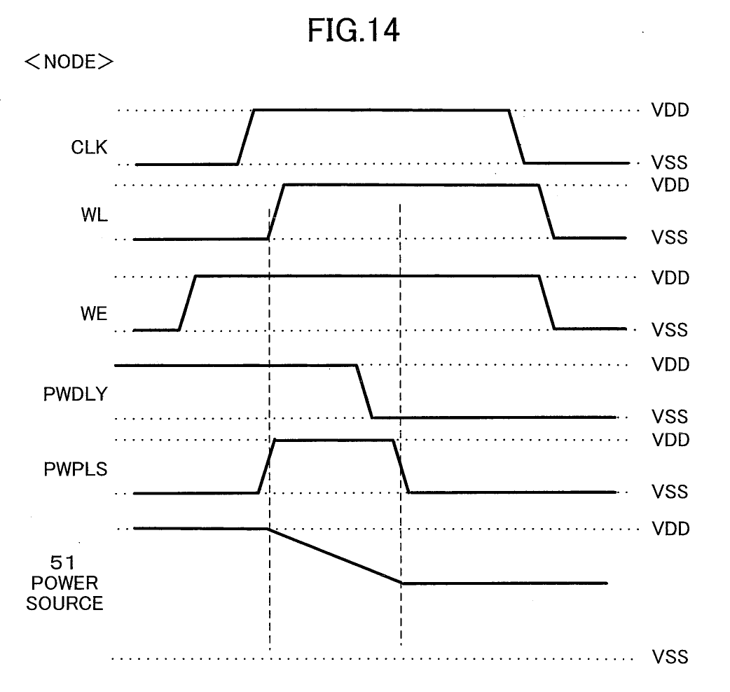

FIG. 14 is a timing chart for showing the operation performed in the SRAM 100 of FIG. 1 in employing the write auxiliary circuit 50. As described above, the pulse edge of the write auxiliary pulse signal PWPLS corresponding to the input signal of the write auxiliary circuit 50 is generated based on a write pulse forming signal PWDLY5. At this point, in process variation that makes a write operation most difficult to perform, namely, in the case where the driving performance of a P-type transistor is high and the driving performance of an N-type transistor is low, the delay clock circuit 16, 19 or 22 can delay the activation timing as compared with the conventional delay clock circuit 10. Accordingly, since the activation of the write pulse forming signal PWDLY is delayed, the pulse width of the write auxiliary pulse signal PWPLS is increased. Therefore, the potential of the power source 51 corresponding to the output of the write auxiliary circuit 50 can be lowered so that the write operation can be easily performed.

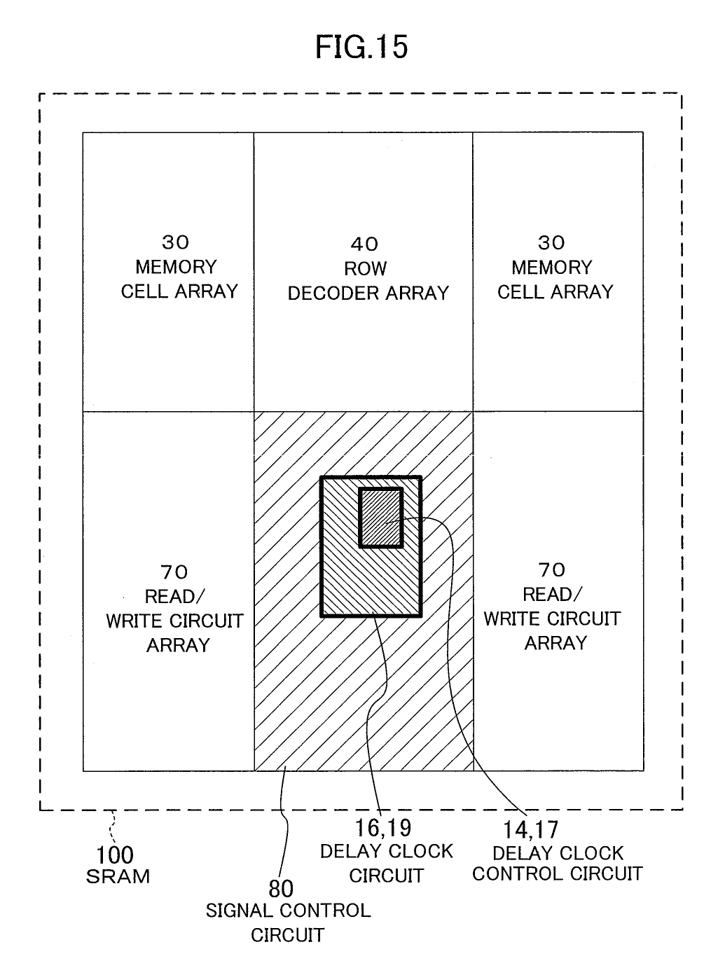

FIG. 15 is a diagram for schematically showing an exemplified layout of the SRAM 100 of FIG. 1. In the layout of FIG. 15, a reference numeral 16 or 19 denotes a delay clock circuit, a reference numeral 30 denotes a memory cell array, a reference numeral 40 denotes a row decoder array, a reference numeral 70 denotes a read/write circuit array including a plurality of read/write circuits arranged in the form of a column, and a reference numeral 80 denotes a signal control circuit. A delay clock control circuit 14 or 17 is provided in a position farther from the memory cell array 30, the row decoder array 40 and the read/write circuit array 70 than the delay clock circuit 16 or 19.

When the delay clock control circuit 14 or 17 is provided within the signal control circuit 80 as in the layout of FIG. 15, the increase of the layout area can be suppressed so as to secure wiring resources for the row decoder array 40 and the read/write circuit array 70.

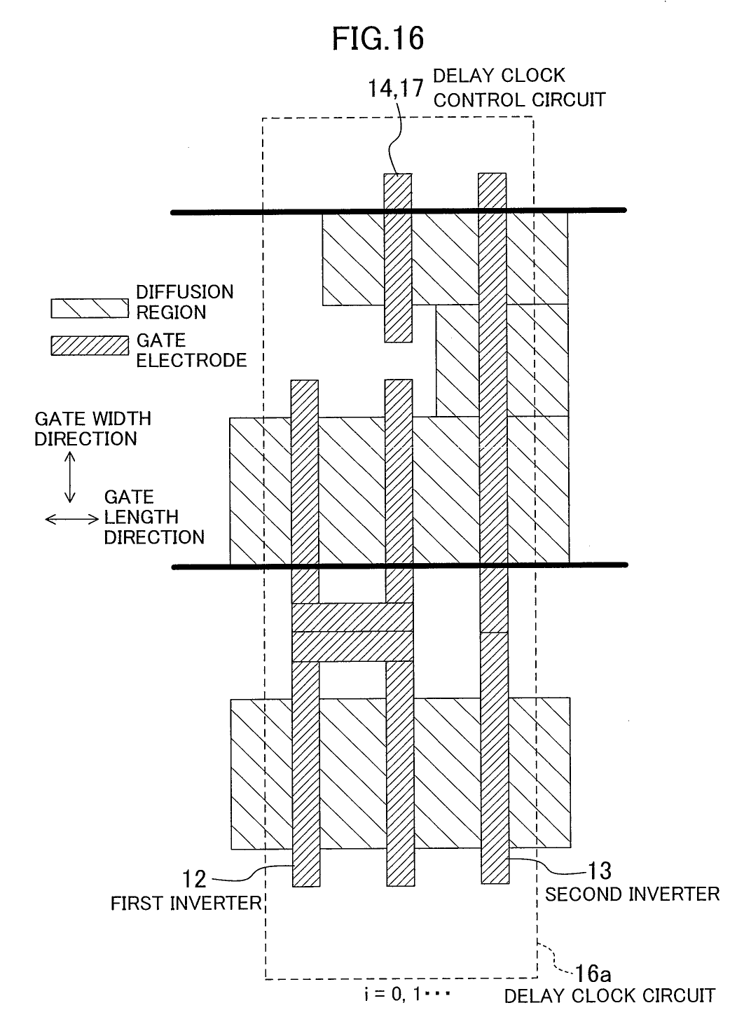

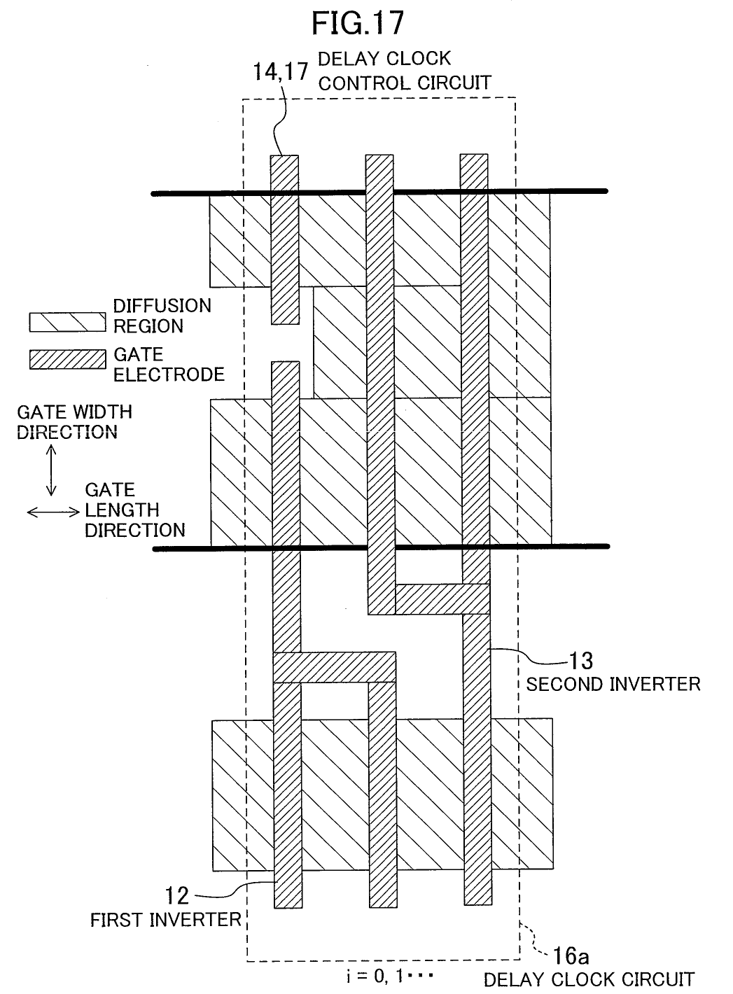

FIGS. 16 and 17 are diagrams for schematically showing exemplified layouts of the delay clock circuits 16a of FIGS. 3 and 7. In each of FIGS. 16 and 17, when an extending direction of a gate electrode is defined as a gate width direction and a vertical direction to the gate width direction is defined as a gate length direction, in the delay clock circuit 16a, the source and the drain of the P-type transistor of the first inverter 12 and the source and the drain of the P-type transistor of the second inverter 13 are laid out substantially straightway along the gate length direction. Also, the source and the drain of the P-type transistor of the second inverter 13 and the source and the drain of the first P-type transistor 15 included in the delay clock control circuit 14 or 17 are laid out substantially straightway along the gate length direction.

In this manner, in each of the layouts of FIGS. 16 and 17, the diffusion regions are laid out substantially straightway in the gate length direction. Therefore, the characteristic variation of the transistors can be reduced. As a result, the timing variation of a signal output from the delay clock circuit 16a can be suppressed.

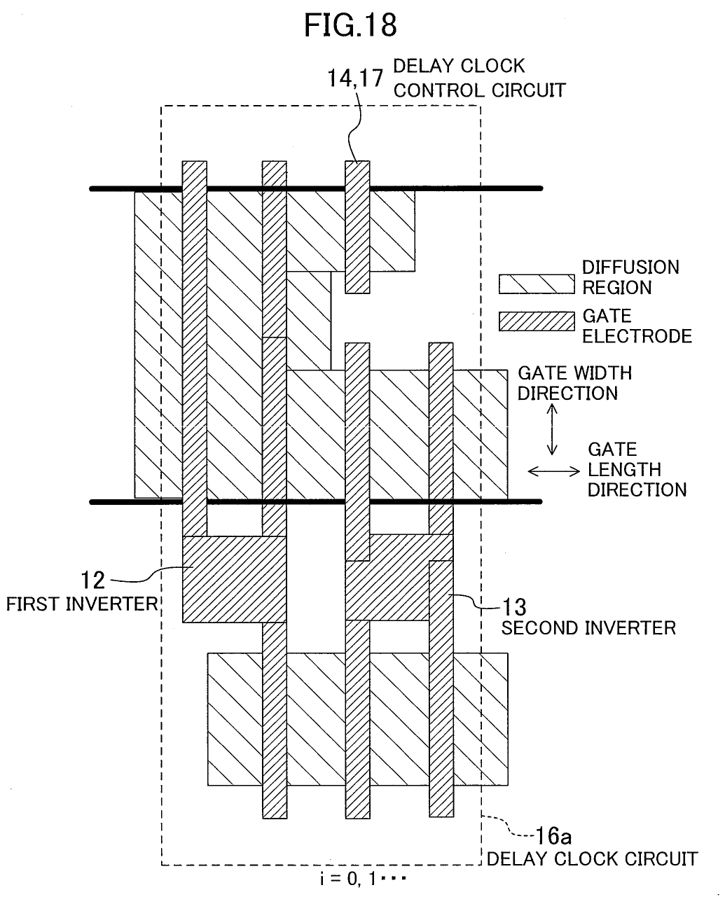

FIG. 18 is a diagram for schematically showing an exemplified layout of the delay clock circuits 16a of FIGS. 3 and 7. In FIG. 18, when an extending direction of a gate electrode is defined as a gate width direction and a vertical direction to the gate width direction is defined as a gate length direction, in the delay clock circuit 16a, the source and the drain of the P-type transistor of the first inverter 12 and the source and the drain of the P-type transistor of the second inverter 13 are laid out substantially straightway along the gate length direction. Also, the source and the drain of the P-type transistor of the first inverter 12 and the source and the drain of the first P-type transistor 15 included in the delay clock control circuit 14 or 17 are laid out substantially straightway along the gate length direction.

In this manner, in the layout of FIG. 18, the diffusion regions are laid out substantially straightway in the gate length direction. Therefore, the characteristic variation of the transistors can be reduced. As a result, the timing variation of a signal output from the delay clock circuit 16a can be suppressed.

It is noted that the present invention is not limited to the aforementioned embodiment and can be variously modified within the true spirit and scope of the invention. For example, although the description is herein given on the SRAM, the invention can be modified to be applied to a DRAM or another semiconductor memory.

According to the present invention, a semiconductor integrated circuit can be provided with transistor variation tolerance without increasing the circuit area. Accordingly, the invention is useful for, for example, a semiconductor memory including a sense amplifier, such as an SRAM, and more specifically, a cache memory or the like for a microprocessor.

What is claimed is:

1. A semiconductor integrated circuit comprising a delay clock circuit for delaying an input clock signal,
the delay clock circuit including cascade connection of components each comprising first and second inverters,
each of the components including a delay clock control circuit operated in such a manner that a through current passes through a connection node between the first and second inverters for causing charge competition for a given period of time in transition of an input to the component.

2. The semiconductor integrated circuit of claim 1,
wherein the given period of time is shorter than a rising edge interval of the input clock signal.

3. The semiconductor integrated circuit of claim 1,
wherein the delay clock control circuit includes a first P-type transistor disposed between a power line and the connection node for receiving an output of the second inverter at a gate thereof, and
the first inverter includes a plurality of N-type transistors disposed between a ground line and the connection node and serially connected to one another in plural stages.

4. The semiconductor integrated circuit of claim 3,
wherein a sum of gate widths of the plurality of N-type transistors is not less than twice and not more than 40 times as large as a gate width of the first P-type transistor.

5. The semiconductor integrated circuit of claim 3,
wherein the delay clock control circuit includes a second P-type transistor disposed between the power line and the connection node for receiving a first external signal at a gate thereof.

6. The semiconductor integrated circuit of claim 5,
wherein a sum of gate widths of the plurality of N-type transistors is not less than twice and not more than 40 times as large as a sum of gate widths of the first and second P-type transistors.

7. The semiconductor integrated circuit of claim 5,
wherein the first external signal is a signal for switching between a normal operation and a test operation and is used for turning the second P-type transistor on in the test operation.

8. The semiconductor integrated circuit of claim 3,
wherein the delay clock circuit further includes a body control circuit for controlling body potential of the first P-type transistor and the plurality of N-type transistors in accordance with a second external signal.

9. The semiconductor integrated circuit of claim 8,
wherein the second external signal is a signal for switching between a normal operation and a test operation, and
the body control circuit applies a forward bias to a body of the first P-type transistor and a reverse bias to a body of the plurality of N-type transistors in the test operation.

10. The semiconductor integrated circuit of claim 1, further comprising:
a memory cell array in which a plurality of memory cells are arranged in a form of a matrix;
a plurality of word lines provided correspondingly to rows of the memory cells;
a plurality of bit line pairs provided correspondingly to columns of the memory cells;
a sense amplifier for amplifying a micro potential difference in each of the bit line pairs; and
a row decoder for outputting a pulse signal to a corresponding word line when selected by an address signal,
wherein the sense amplifier receives a delay clock signal output from the delay clock circuit as a sense amplifier enable signal, and
the row decoder receives a delay clock signal output from the delay clock circuit as a word line pulse forming signal used for forming a pulse edge of the pulse signal.

11. The semiconductor integrated circuit of claim 10, further comprising a row decoder replica that has a same configuration as the row decoder, does not receive the address signal and outputs a pulse signal at a same timing as the selected row decoder,
wherein the pulse signal output from the row decoder replica is input to the delay clock circuit as the input clock signal.

12. The semiconductor integrated circuit of claim 5, further comprising:
a memory cell array in which a plurality of memory cells are arranged in a form of a matrix;
a plurality of word lines provided correspondingly to rows of the memory cells;
a plurality of bit line pairs provided correspondingly to columns of the memory cells;
a sense amplifier for amplifying a micro potential difference in each of the bit line pairs;
a memory cell replica array in which a plurality of memory cell replicas each having a same structure as the memory cell are arranged in a form of a column; and
a replica bit line pair provided correspondingly to the column of the memory cell replicas,
wherein the sense amplifier receives a delay clock signal output from the delay clock circuit as a sense amplifier enable signal, and
the delay clock circuit receives, at the gate of the second P-type transistor of the delay clock control circuit, a signal indicating whether or not a given potential difference is caused in the replica bit line pair instead of the first external signal.

13. The semiconductor integrated circuit of claim 1, further comprising:
a memory cell array in which a plurality of memory cells are arranged in a form of a matrix; and
a write auxiliary circuit provided correspondingly to each column of the memory cells for lowering potential of a power source of the corresponding memory cells while a write auxiliary pulse signal is output,
wherein a pulse edge of the write auxiliary pulse signal is formed based on a delay clock signal output from the delay clock circuit.

14. The semiconductor integrated circuit of claim 3,
wherein in the delay clock circuit, a source and a drain of a P-type transistor of the first inverter and a source and a drain of a P-type transistor of the second inverter are laid out substantially straightway, and the source and the drain of the P-type transistor of the second inverter and a source and a drain of the first P-type transistor included in the delay clock control circuit are laid out substantially straightway.

15. The semiconductor integrated circuit of claim 3,
wherein in the delay clock circuit, a source and a drain of a P-type transistor of the first inverter and a source and a drain of a P-type transistor of the second inverter are laid out substantially straightway, and the source and the drain of the P-type transistor of the first inverter and a source and a drain of the first P-type transistor included in the delay clock control circuit are laid out substantially straightway.
